(19) United States
(12) Patent Application Publication
(10) Pub. No.: US 2007/0240636 A1
(43) Pub. Date: Oct. 18, 2007

(54) Thermal Vacuum Deposition Method and Device

(75) Inventors: Lutz Gottsman, Kleinroehrsdorf (DE); Ulf Seyfert, Dresden (DE); Bernd-Dieter Wenzel, Grossharthau-Buehlau (DE); Reinhard Jaeger, Coswig (DE)

Correspondence Address: HESLIN ROTHENBERG FARLEY & MESITI PC, 5 COLUMBIA CIRCLE, ALBANY, NY, 12203, US

(73) Assignee: VON ARDENNE ANLAGENTECHNIK GMBH, Dresden (DE)

(21) Appl. No.: 11/568,332

(22) PCT Filed: Apr. 16, 2005
(86) PCT No.: PCT/DE05/00702

§ 371 Date: Feb. 23, 2007

(30) Foreign Application Priority Data
Apr. 27, 2004 (DE) 10 2004 020 842.5
Aug. 27, 2004 (DE) 10 2004 041 854.3

(51) Int. Cl. C23C 14/00

(52) U.S. Cl. 118/50; 427/294

(57) ABSTRACT

A thermal vacuum deposition device and method in which a band-shaped substrate is continuously conveyed in a vaporization channel that is charged with a vaporous coating material is characterized in that the vaporization channel is sealed by inserting at least one positionally adjustable hollow element into an outer space of the vaporization channel and an inner space of the vaporization channel when a minimum conveying speed is not attained or when the substrate is at a standstill such that the substrate is located in the inner space.

The invention relates to a method and device for thermal vacuum deposition of a continuously conveyed substrate through evaporation of solid and/or liquid coating materials and vapor deposition of the vaporous coating material on the substrate in which the substrate is moved in a heated vaporization channel, the vaporization channel is arranged in a vacuum chamber and connected to an evaporation apparatus and the vaporization apparatus as well as the evaporation apparatus are the main parts of a deposition apparatus.

Various deposition methods for physical vapor deposition (PVD) in a vacuum are known. The deposition systems used for this are distinguished according to systems with a static or continuous method. In contrast to the static method, a substrate is conveyed constantly through the deposition apparatus in the continuous method. Accordingly, coating material is continuously supplied to the vaporization channel of the deposition apparatus in the form of vapor.

Such systems are particularly used for the deposition of band-shaped steel substrates with a band width from the centimeter scale to the meter scale. For commercial use of a system according to the continuous deposition method, there is a need for continuous stocking up of the deposition apparatus with coating material without interrupting the continuous substrate conveyance.

In the conventional deposition method, temperatures that are suitable for influencing the mechanical properties of the substrate are applied in the vaporization channel. For this reason, precise coordination of the temperature in the vaporization channel and the conveying speed of the substrate is essential and must be maintained. If any conveying fault occurs, for example a reduction of the conveying speed or standstill of the substrate in the vaporization channel at an even surface temperature of the vaporization channel, the substrate can be heated up so much that it is damaged, causing its physical properties to change to such an extent that it is unusable. In particular, cracking of the substrate band is associated with significant time and cost requirements for maintenance due to the usual system size and the special process conditions.

The object of this invention is therefore to allow the substrate to be quickly protected against damage during the coating process in previously known deposition methods and devices, particularly in the context of changing parameters of the coating process, such as the substrate speed.

The object is achieved in an inventive method in that the vaporization channel is sealed by inserting at least one positionally adjustable hollow element into an outer space and an inner space when a minimum conveying speed is not attained or when the substrate is at a standstill such that the substrate is located in the inner space.

Therefore, in the instance where the substrate is exposed to the radiant heat of the heated vaporization channel for more time than the design allows for, the substrate located in the vaporization channel is thermally protected by the hollow element arranged between the substrate and the hot vaporization channel surface and, in such a fault instance, the substrate is not exposed to any thermal loads.

In addition, the insertion of a hollow element enables the substrate to be protected very quickly, and protection can also be automated by means of suitable movement and temperature monitoring.

Another particular advantage of the insertion according to the invention of a hollow element into the space between the vaporization channel surface and the substrate is that the vaporous coating material flowing in the channel surface through nozzles, for example, is largely deposited on the hollow element and not on the substrate. In this way, uncontrolled deposition of the substrate can be prevented in the event of a fault. Furthermore, due to the good sealing of the substrate with an introduced hollow element, it is possible to close the substrate protection device according to the invention in order to condition the evaporation system, as contamination of the layer on the substrate section located within the vaporization channel can thus be prevented.

In a particularly advantageous embodiment of the method, provision is made for two hollow elements to be inserted towards each other and for the two facing front ends of the two hollow elements to be positioned together in the inserted state.

By introducing two hollow elements into the vaporization channel, comparatively short travel distances of the hollow elements are possible, thus increasing the advantage of quickly available substrate protection and reducing the additional space requirement for provision of the hollow element in a standby position, particularly as the dimensions of a vaporization system are usually very considerable. In addition, the force required to move the hollow element, which is to be applied by means of suitable transfer means inside the vaporization element, can be significantly reduced. For example, in the conventional vertical arrangement of a vaporization chamber, the weight pressure of one hollow element can be used to move the other hollow element by means of a corresponding force transfer.

It is also useful if the hollow element(s) travels/travel in the vacuum chamber surrounding the vaporization channel. The vaporization channel has an opening on the inlet side for inserting the hollow element. The hollow element is thus in the standby position and the application position as well as every intermediate position in the vacuum chamber so that influencing of the process parameters such as pressure is avoided within the vacuum chamber. In addition, this embodiment of the invention is suitable for ensuring particularly quick protection of the substrate.

In another advantageous embodiment of the method, provision is made for the hollow element to be inserted parallel to the conveying direction of the band-shaped substrate. The hollow element therefore rests in the standby position in the immediate vicinity of the vaporization channel and is already precisely positioned in this location relative to the moved substrate such that only a parallel shift of the hollow element is required. Therefore, all that's needed to protect the substrate is the completion of a simple linear movement of the protection element.

Furthermore, it is expedient if the hollow element is cooled using a suitable method, as the thermal energy absorbed by the hollow element is thus dissipated. This particularly ensures that whilst the hollow element is present in the hot vaporization channel, the vaporous coating material is always deposited on the hollow element and its heating up is delayed or even prevented, so that no recurrent evaporation of the material briefly deposited on the inserted, relatively cold hollow element occurs. It is particularly preferable if the cooling is therefore performed actively by means of a coolant liquid. This cooling can be ensured irrespective of the duration of the presence of the hollow element in the hot vaporization channel.

To interrupt further charging of the vaporization channel with vaporous coating material, charging of the deposition chamber with coating material is usefully prevented through the closing of a valve in the event of a fault. The vaporous coating material already in the vaporization channel and the pipe is mostly fully deposited on the cold surface of the hollow element inserted in the vaporization channel as a result of the interruption of the supply. As the other surfaces of the vaporization channel continue to be heated until the largely complete depositing of the remaining vaporous coating material, the coating material is largely only deposited on the hollow element.

On the arrangement side, the objective is achieved by means of a device according to the invention for substrate deposition according to the characteristics of claim 7. According to claim 7, when a minimum conveying speed of the substrate is not attained or when the substrate is at a standstill, at least one hollow element that can be inserted in the vaporization channel surrounds the substrate. Therefore the substrate resting in the vaporization channel is thermally protected by the hollow element arranged between the substrate and a heating apparatus. In such a fault instance, the substrate is therefore exposed to lower thermal loads. In addition, the inflowing vaporous coating material is largely deposited on the hollow element.

To ensure the least complex possible mode of operation that is also reliable by means of a single-part functional component, it is advantageous for the hollow element to be a prismatic or cylindrical hollow element. For its continuous conveying, the substrate is guided through the hollow element so that a full protective element is provided by means of the hollow element.

In another special embodiment, provision is made for the hollow element to be arranged, when regular, continuous substrate conveying is carried out at least at the minimum speed, in a standby position outside the vaporization channel and inside the vacuum chamber and also, if applicable, in an application position largely in the vaporization channel when the minimum conveying speed of the substrate is not attained or when the substrate is at a standstill. In this respect, the hollow element can always remain arranged totally in the vacuum chamber and seal with the wall of the vaporization channel in the insertion area.

If two hollow elements are largely arranged in the deposition chamber in an application position in accordance with another embodiment of the deposition apparatus according to the invention, the hollow elements form an optically tight partition into an inner and outer section of the vaporization channel, as a result of which the described advantages in terms of the separation of the substrate located in the vaporization channel can be increased and the system-related costs for the substrate protection device can be optimized.

Usefully, the hollow element wall can be made from high-temperature steel or a high-temperature alloy. In any case, the hollow element wall has thermal and therefore also mechanical stability up to a temperature range of 800° C., preferably up to 1000° C., which is sufficient even in the event of a fault.

In order to attain thermal insulation of the two spaces in relation to each other, the hollow element has an inner hollow element wall and an outer hollow element wall positioned at a distance therefrom, so that an interspace is created. The interspace is formed between the two walls fully on the hollow element.

In this way, cooling of the hollow element can be enabled by filling the interspace between the inner hollow element wall and the outer hollow element wall with a coolant liquid. The coolant liquid absorbs the heat transferred to the walls. Particularly advantageously, the coolant liquid is exchanged, and the absorbed heat is thus taken up.

Water or any other liquid with a high thermal capacity is used as a liquid. In particular, water is used as a liquid, as water is easily available. For effective cooling, the liquid is guided through the interspace. In addition, by installing walls in the interspace and a resultant channel environment, the flow direction and flow speed can be specified in design terms. The smaller the channel cross-section, the higher the flow speed at a constant flow volume. For cooling, cold liquid enters into the interspace and warm liquid comes back out. Cooling can also be inactive when the hollow element is in the standby position, i.e. the liquid rests in the interspace. At the time of application, cooling is then activated in that the liquid is guided through. Alternatively, cooling can be constantly active in order to guarantee function and fast applicability.

It is useful for the hollow element to be mounted on rollers and/or rails so that the hollow element can move in a defined manner and damage to the vacuum chamber or vaporization channel during movement is reliably prevented. The guide is formed in a vacuum-compatible and thermally stable manner under the operating conditions. For moving the hollow element, it is particularly useful for the substrate protection device to have at least one drive. The drive is preferably arranged outside the vacuum chamber and operates via one or more transmission members on the hollow element in this instance.

Ropes, bands, belts, chains, toothed belts or the like, for example, are provided as means of transmission. In this respect, the effective direction of the force is directionally changed via guide rollers. Alternatively, the driving force is transferred to the hollow element by means of an extendable device, by means of a device with a toothed rack guide or the like, for example. The means of transmission and, if applicable, the deflections are formed in a vacuum-compatible and thermally stable manner under the operating conditions.

The invention is described in more detail below on the basis of an execution example. In the associated drawings,

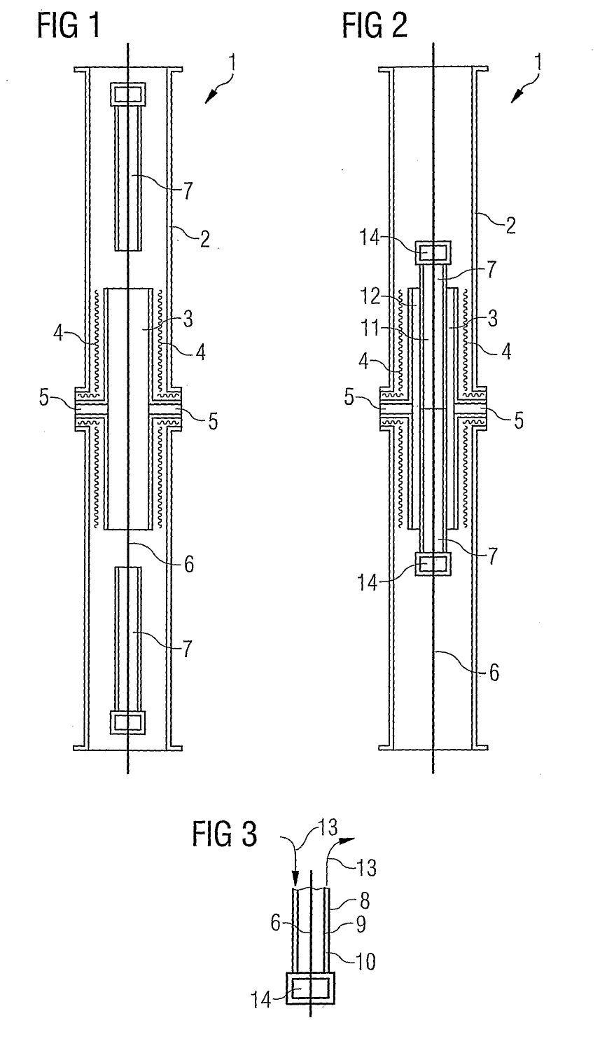

FIG. 1 shows a schematic representation of a vertical cross-section of a deposition apparatus according to the invention with a substrate protection device

FIG. 2 shows the deposition apparatus according to FIG. 1 with the substrate protection device in the operating position and

FIG. 3 shows a schematic representation of a vertical cross-section of a hollow element.

Regarding the object:

FIG. 1 shows a deposition apparatus 1 according to the invention with a vacuum chamber 2 and a vaporization channel 3 arranged therein. The vaporization channel 3 has a height of around 4 meters and is arranged at mid-level of the around 10-metre-high vacuum chamber 2. The vaporization channel 3 has the shape of a tall, elongated, hollow cuboid and is opened at the base at the top and bottom end.

At mid-level of the vacuum chamber 2 and of the vaporization channel 3, a nozzle 5 largely horizontally aligned in the operating position is mounted on two opposing sides, either side of the substrate, which nozzle feeds into the vaporization channel 3 with its narrow end. The other end of the nozzle 5 is connected to an evaporation apparatus, which is used for evaporating the coating material.

A band-shaped substrate 6 is conveyed through the vacuum chamber 2 and the vaporization channel 3. The substrate 6 is aligned in such a way that the surfaces are oriented crosswise to the nozzle, the nozzle pointing towards the surface center of the substrate in each case. The substrate can be already coated in a preceding deposition run.

The hollow element according the invention is also located in the vacuum chamber 2 as a substrate protection apparatus. This consists of two linearly mobile units. Each unit comprises a hollow cuboid 7, which is opened at the sides of the bases for guiding through the substrate band 6. The dimensions of the base of one hollow cuboid 7 are smaller than the dimensions of the base of the vaporization channel 3, and the height of one hollow cuboid 7 slightly exceeds half the height of the vaporization channel 3. Furthermore, the hollow cuboids 7 are mounted in a parallel mobile manner pointing towards each other, around the substrate band 6 and towards the conveying direction of the substrate band 6.

In the standby position, a hollow cuboid 7 is supported above and below the vaporization channel 3 (FIG. 1). In the application position, i.e. after the two hollow cuboids have been introduced into the vaporization channel, the two hollow cuboids 7 meet with their opposing front ends at the level of the nozzles 5. In the contact plane of the two hollow cuboids 7, these lie on top of each other in a vapor-tight manner so that the vaporization channel 3 is divided into an inner vaporization channel 11 and an outer vaporization channel 12 (FIG. 2).

The coolant water supply of the hollow cuboids 7 is, for example, effected via meandering hose connections not shown in more detail here that are adapted to the distance differences of the hollow cuboids 7 by means of opening of their bending radius.

FIG. 3 shows a cross-section of a hollow cuboid. Between an outer hollow element wall 8 and an inner hollow element wall 9, the hollow cuboid 7 extensively forms an interspace 10 that serves as a channel system. Water as a coolant liquid 13 is guided through the channel system at a defined flow speed.

Each hollow cuboid 7 is guided on guide rails which are not described in more detail. For suspension, the hollow cuboid 7 has a cross strut 14 on the base opposing the other hollow cuboid. Due to the length of the hollow cuboid, which is greater than half the length of the vaporization channel by at least one cross-section of the cross strut, the suspension cross struts project from the vaporization channel 3.

Outside the vacuum chamber 2, a drive that is also not described in more detail is mounted with a shaft extending into the vacuum chamber 2. The drive shafts are connected to the two hollow cuboids 7 by means of traction means guided via guide rollers.

Regarding the method:

The deposition method is a continuous thermal vacuum deposition of the band-shaped substrate through evaporation of solid coating material and vapor deposition of the vaporous coating material on the continuously conveyed substrate in the vaporization channel 3.

To achieve this, the solid coating material is heated in a vacuum and conveyed through the nozzle 5 on both sides of the substrate into the heated and evacuated vaporization channel 3. By means of a vapor-tight valve present on the evaporation apparatus, the inflow of vaporous coating material can be regulated and also interrupted.

In the vaporization channel 3, the band-shaped steel substrate 6 is conveyed—the conveying speed varies, and is between 30 meters per minute and 200 meters per minute in the execution example.

The conveying of the substrate is monitored with sensors via a computer-aided control unit. As soon as a fault occurs in the conveying of the substrate and the substrate 6 does not emerge from the hot evaporation channel 3 quickly enough or at all, a fault is registered.

In this case, the two hollow cuboids 7 supported outside, i.e. above and below the vaporization channel 3 in the vacuum chamber 4, run in to the vaporization channel and collide as a thermal protective curtain. In the contact plane, the two hollow cuboids 7 are so close together that no vaporous coating material penetrates the inner vaporization chamber. During the deposition process, the interspace 10 is filled with cooling water 11, which is guided through the interspace 10.

Also by means of a control unit, the further charging of the vaporization channel (3) with trailing vaporous coating material is prevented. The vaporous coating material located in the vaporization channel 3 and in the conveying lines present between the evaporation and vaporization apparatus is deposited on the cooled outer hollow element wall 8 and the cooled inner hollow element wall 9. At least the inner vaporization chamber is subsequently largely free of condensation of the coating material.

In the event of a fault, the heating of the vaporization channel is continued. In this way, the vaporous coating material is largely completely deposited on the inner and outer hollow element wall 8, 9 of the hollow cuboids 7.

### LIST OF NUMERALS

1 Deposition apparatus
2 Vacuum chamber
3 Vaporization channel
4 Heating apparatus
5 Nozzle
6 Substrate
7 Hollow element, hollow cuboids
8 Outer hollow element wall
9 Inner hollow element wall
10 Interspace
11 Inner vaporization channel
12 Outer vaporization channel
13 Coolant liquid
14 Cross strut

1. Method for thermal vacuum deposition of a continuously conveyed substrate through evaporation of solid and/or liquid coating materials and vapor deposition of vaporous coating material on the substrate, wherein the substrate is moved in a heated vaporization channel of a vaporization apparatus, and the vaporization channel is sealed by inserting at least one positionally adjustable hollow element into an outer space and an inner space when a minimum conveying speed is not attained or when the substrate is at a standstill such that the substrate is located in the inner space.

2. Method according to claim 1, wherein two hollow elements are inserted towards one another and two facing front ends of the two hollow elements are positioned together in an inserted state.

3. Method according to claim 1, wherein the hollow element travels in a vacuum chamber surrounding the vaporization channel.

4. Method according to claim 1, wherein the hollow element is inserted parallel to a conveying direction of the substrate.

5. Method according to claim 1, wherein the hollow element is cooled.

6. Method according to claim 1, wherein charging of the vaporization channel with vaporous coating material is prevented when a minimum conveying speed of the substrate is not attained or when the substrate is at a standstill.

7. Deposition apparatus particularly for thermal vacuum deposition of continuously conveyed substrate comprising a vaporization apparatus, a vacuum chamber and a vaporization channel arranged in the vacuum chamber and surrounding the substrate, and an evaporation apparatus connected to the vaporization channel, wherein when a minimum conveying speed of the substrate is not attained or when the substrate is at a standstill, at least one hollow element that can be inserted in the vaporization channel surrounds the substrate.

8. Deposition apparatus according to claim 7, wherein the hollow element comprises a prismatic or cylindrical hollow element.

9. Deposition apparatus according to claim 7, wherein when continuous substrate conveying is carried out at least at the minimum speed, the hollow element is arranged in a standby position outside the vaporization channel and inside the vacuum chamber.

10. Deposition apparatus according to claim 7, wherein the hollow element is largely arranged in the vaporization channel when a minimum conveying speed of the substrate is not attained or when the substrate is at a standstill.

11. Deposition apparatus according to claim 7, wherein two hollow elements are arranged in an application position largely in the vaporization channel, facing front ends of the two hollow elements being positioned together.

12. Deposition apparatus according to claim 7, wherein the hollow element comprises high-temperature steel or a high-temperature alloy.

13. Deposition apparatus according to claim 7, wherein the hollow element has an inner hollow element wall, and an outer hollow element wall positioned at a distance from the inner wall, that create an interspace.

14. Deposition apparatus according to claim 7, wherein the hollow element is mounted on rollers and/or rails.

15. Deposition apparatus according to claim 7, wherein the hollow element is mobile by a drive.

16. Deposition apparatus according to claim 15, wherein the hollow element is connected to the drive via a transmission.
